(19) United States
(12) Patent Application Publication
(10) Pub. No.: US 2013/0313561 A1
(43) Pub. Date: Nov. 28, 2013

(54) GROUP III-NITRIDE TRANSISTOR WITH CHARGE-INDUCING LAYER

(71) Applicant: Chang Soo Suh, Allen, TX (US)

(72) Inventor: Chang Soo Suh, Allen, TX (US)

(73) Assignee: TRIQUINT SEMICONDUCTOR, INC., Hillsboro, OR (US)

(21) Appl. No.: 13/481,198

(22) Filed: May 25, 2012

(51) Int. Cl. H01L 29/225; H01L 21/338

(52) U.S. Cl. 257/76; 438/172; 257/E21.403; 257/E29.091

(57) ABSTRACT

Embodiments of the present disclosure describe apparatuses, methods, and systems of a device such as a transistor. The device includes a buffer layer disposed on a substrate, the buffer layer being configured to serve as a channel of a transistor and including gallium (Ga) and nitrogen (N), a barrier layer disposed on the buffer layer, the barrier layer being configured to supply mobile charge carriers to the channel and including aluminum (Al), gallium (Ga), and nitrogen (N), a charge-inducing layer disposed on the barrier layer, the charge-inducing layer being configured to induce charge in the channel and including aluminum (Al) and nitrogen (N), and a gate terminal disposed in the charge-inducing layer and coupled with the barrier layer to control the channel. Other embodiments may also be described and/or claimed.

### FIELD

Embodiments of the present disclosure generally relate to the field of integrated circuits, and more particularly, to a group III-Nitride transistor with a charge-inducing layer and method of fabrication.

### BACKGROUND

Presently, group III-Nitride-based transistors such as gallium nitride (GaN)-based high electron mobility transistors (HEMTs) are typically Depletion-mode (D-mode) devices, which use a negative gate voltage with respect to source voltage in order to pinch-off current flow in the transistor. However, Enhancement-mode (E-mode) devices (sometimes referred to as “normally-off devices”), which use a positive gate voltage with respect to source voltage in order to turn-on or enhance current flow in the transistor, may be desirable for applications such as power switching. E-mode devices can be fabricated by controlling a thickness of a supply layer to be less than a critical thickness such that a two-dimensional electron gas (2DEG) does not form in the conductive channel beneath the gate (e.g., when no external voltage is applied to the gate of the transistor or when the gate voltage is equal to the source voltage). Higher charge densities in the region adjacent to the gate may be desired to achieve lower on-resistance for such transistors. However, increasing a charge density by using a supply layer that provides higher charge densities may require a smaller critical thickness of the supply layer in, for example, GaN-based HEMTs. For example, when a supply layer is designed to provide high charge density, a thickness that is smaller than the critical thickness of the supply layer may be too small for current manufacturing equipment to reliably produce.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example and not by way of limitation in the figures of the accompanying drawings.

FIG. 1 schematically illustrates a cross-section view of a device, according to various embodiments.

FIG. 2 is a graph of channel charge density (nₛ) and barrier thickness for a variety of example barrier layer materials, according to various embodiments.

FIG. 3 schematically illustrates a cross-section view of a device subsequent to formation of a stack of layers on a substrate, according to various embodiments.

FIG. 4 schematically illustrates a cross-section view of a device subsequent to formation of a source and drain, according to various embodiments.

FIG. 5 schematically illustrates a cross-section view of a device subsequent to formation of a gate, according to various embodiments.

FIG. 6 schematically illustrates a cross-section view of a device subsequent to formation of a gate having an integrated field-plate, according to various embodiments.

FIG. 7 schematically illustrates a cross-section view of a device subsequent to formation of an additional source-connected field-plate, according to various embodiments.

FIG. 8 is a flow diagram of a method for fabricating a device, according to various embodiments.

FIG. 9 schematically illustrates an example system including a device, according to various embodiments.

### DETAILED DESCRIPTION

Embodiments of the present disclosure provide techniques and configurations for a group III-Nitride transistor with a charge-inducing layer. In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous. The term “coupled” may refer to a direct connection, an indirect connection, or an indirect communication.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other.

In various embodiments, the phrase “a first layer formed, disposed, or otherwise configured on a second layer,” may mean that the first layer is formed, disposed, or otherwise configured over the second layer, and at least a part of the first layer may be in direct contact (e.g., direct physical and/or electrical contact) or indirect contact (e.g., having one or more other layers between the first layer and the second layer) with at least a part of the second layer.

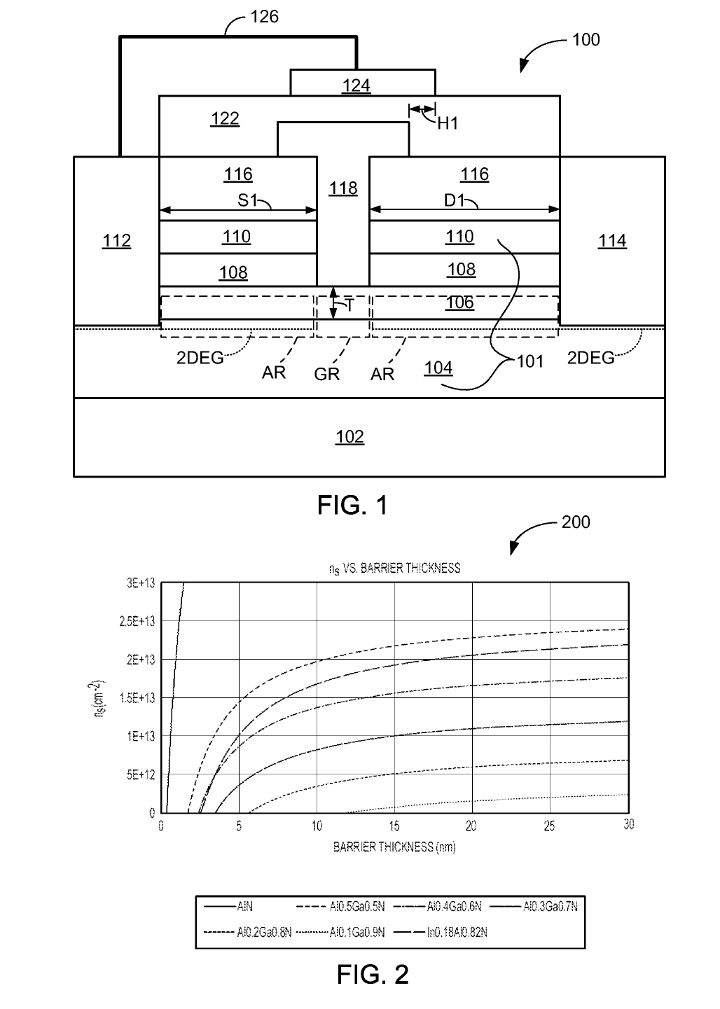

FIG. 1 schematically illustrates a cross-section view of a device 100, according to various embodiments. The device 100 may represent an integrated circuit device such as a transistor in some embodiments. The device 100 may be fabricated on a substrate 102. The substrate 102 generally includes a support material upon which a stack of layers (or simply “stack 101”) is deposited. In an embodiment, the substrate 102 includes silicon (Si), silicon carbide (SiC), aluminum oxide (Al₂O₃), diamond (C), glass (SiO₂) or “sapphire,” gallium nitride (GaN), and/or aluminum nitride (AlN). Other materials including suitable group II-VI and group III-V semiconductor material systems can be used for the substrate 102 in other embodiments. In an embodiment, the substrate 102 may be composed of any material or combination of materials upon which material of the buffer layer 104 can be epitaxially grown. The material of the substrate 102 may be grown in the (0001) direction in some embodiments.

The stack 101 formed on the substrate 102 may include epitaxially deposited layers of different material systems that form one or more heterojunctions/heterostructures. The layers of the stack 101 may be formed in situ. That is, the stack 101 may be formed on the substrate 102 in manufacturing equipment (e.g., a chamber) where the constituent layers of the stack 101 are formed (e.g., epitaxially grown) without removing the substrate 102 from the manufacturing equipment.

In one embodiment, the stack 101 of the device 100 includes a buffer layer 104 formed on the substrate 102. The buffer layer 104 may provide a crystal structure transition between the substrate 102 and other components (e.g., barrier layer 106) of the device 100, thereby acting as a buffer or isolation layer between the substrate 102 and other components of the device 100. For example, the buffer layer 104 may provide stress relaxation between the substrate 102 and other lattice-mismatched materials (e.g., the barrier layer 106). In some embodiments, the buffer layer 104 may serve as a channel for mobile charge carriers of a transistor. The buffer layer 104 may be undoped in some embodiments. The buffer layer 104 may be epitaxially coupled with the substrate 102. In other embodiments, a nucleation layer (not shown) may intervene between the substrate 102 and the buffer layer 104. The buffer layer 104 may be composed of a plurality of deposited films or layers in some embodiments.

In some embodiments, the buffer layer 104 may include a group III-nitride-based material such as, for example, gallium nitride (GaN), indium nitride (InN) or aluminum nitride (AlN). The buffer layer 104 may have a thickness from 0.1 to 1000 microns in a direction that is substantially perpendicular to a surface of the substrate 102 upon which the buffer layer 104 is formed. The buffer layer 104 may include other suitable materials and/or thicknesses in other embodiments.

The stack 101 may further include a barrier layer 106 (sometimes referred to as a “supply layer”) formed on the buffer layer 104. A heterojunction may be formed between the barrier layer 106 and the buffer layer 104. The barrier layer 106 may have a bandgap energy that is greater than a bandgap energy of the buffer layer 104 (e.g., a top-most layer of the buffer layer 104). The barrier layer 106 may be a wider bandgap layer that supplies mobile charge carriers and the buffer layer 104 may be a narrower bandgap layer that provides a channel or pathway for the mobile charge carriers. In some embodiments, the barrier layer 106 may serve as an etch stop layer for a selective etch process that removes material of the charge-inducing layer 108. The barrier layer 106 may be undoped in some embodiments. The barrier layer 106 may be composed of a plurality of deposited films or layers in some embodiments.

The barrier layer 106 may be composed of any of a variety of suitable material systems. The barrier layer 106 may include, for example, aluminum (Al), indium (In), gallium (Ga), and/or nitrogen (N). In one embodiment, the barrier layer 106 may include aluminum gallium nitride (AlₓGa₁₋ₓN), where x is a value from 0 to 1 that represents relative quantities of aluminum and gallium. In some embodiments, the value for x is less than or equal to 0.2. Other values for x can be used in other embodiments. According to various embodiments, the barrier layer 106 may have a lower aluminum content than a charge-inducing layer 108 of the device 100.

A two-dimensional electron gas (2DEG) may be formed at an interface (e.g., the heterojunction) of the buffer layer 104 (e.g., a top-most layer of buffer layer 104) and the barrier layer 106 allowing current (e.g., the mobile charge carriers) to flow between a source terminal, hereinafter source 112, and a drain terminal, hereinafter drain 114. In some embodiments, the device 100 may be an Enhancement-mode (E-mode) device, which uses a positive gate voltage with respect to source voltage in order to turn-on or enhance current flow in the device 100. In such embodiments, the barrier layer 106 (or a combination of supply layers such as the barrier layer 106 and the charge-inducing layer 108) may have a thickness, T, that is less than a critical thickness, Tₒ, for 2DEG formation (e.g., below the critical thickness Tₒ, the 2DEG may not form). For example, the thickness T may be configured to inhibit formation of the 2DEG at a gate region (GR) disposed between the gate 118 and the buffer layer 104, as depicted in FIG. 1. The 2DEG formation may occur in access regions (e.g., AR of FIG. 1) between the gate region GR and the source 112 and between the gate region GR and the drain 114, as depicted in FIG. 1.

In some embodiments, a thickness and aluminum content of the barrier layer 106 may be selected to ensure that all of the 2DEG in the gate region GR is removed for a device 100 that is either a Schottky gate device or a metal-insulator-semiconductor (MIS) gate device. In other embodiments, the device 100 may be a Depletion-mode (D-mode) device, which uses a negative gate voltage with respect to source voltage in order to pinch-off current flow in the device 100.

In some embodiments, the barrier layer 106 has a thickness T that is greater than or equal to 30 angstroms. For example, the barrier layer 106 may have a thickness T that is greater than or equal to 30 angstroms and less than the critical thickness Tₒ. A barrier layer 106 having lower aluminum content (e.g., where x is less than or equal to 0.2 for AlₓGa₁₋ₓN) may allow a thickness of the barrier layer 106 to be greater than or equal to 30 angstroms. Providing a thickness of the barrier layer 106 that is greater than 30 angstroms may increase thickness uniformity of the barrier layer 106 or otherwise facilitate reliable production of the barrier layer 106 using thin-film manufacturing equipment. The barrier layer 106 may include other suitable materials and/or thicknesses in other embodiments.

The stack 101 may further include a charge-inducing layer 108 formed on the barrier layer 106. The charge-inducing layer 108 may be epitaxially coupled with the barrier layer 106. In some embodiments, the charge-inducing layer 108 may be lattice-matched with the buffer layer 104, barrier layer 106 and/or a cap layer 110. The charge-inducing layer 108 may have a bandgap energy that is greater than a bandgap energy of the barrier layer 106. The charge-inducing layer 108 may have a polarization (e.g., net polarization of charge per unit area) that is greater than a polarization of the barrier layer 106. The charge-inducing layer 108 may induce charge in the access regions (e.g., ARs of FIG. 1) where the charge-inducing layer 108 is coupled with the barrier layer 106. The charge-inducing layer 108 may provide the device 100 with a lower on-resistance by increasing 2DEG densities in the access regions (e.g., ARs of FIG. 1). In some embodiments, the charge-inducing layer 108 enables or allows the formation of the 2DEG in the access regions in embodiments where the thickness T of the barrier layer 106 is less than the critical thickness Tₒ to inhibit the formation of the 2DEG in the gate region GR of the device 100.

According to various embodiments, the charge-inducing layer 108 may serve as a threshold voltage (V_{TH}) controlling layer. For example, in embodiments where the aluminum content of the charge-inducing layer 108 is greater than the barrier layer 106, the charge-inducing layer 108 may be selectively etched during formation of a gate terminal, hereinafter “gate 118” to provide the thickness T and uniformity of thickness T of the barrier layer 106, which may affect or control the V_{TH}. For example, the selective etching may stop at the barrier layer 106 or the selective etching may otherwise be configured to provide the thickness T that is less than the critical thickness Tₒ (e.g., by timed etching).

The charge-inducing layer 108 may be composed of any of a variety of suitable material systems. The charge-inducing layer 108 may include, for example, aluminum (Al), indium (In), gallium (Ga), and/or nitrogen (N). In some embodiments, the charge-inducing layer 108 may include aluminum and nitrogen. In an embodiment, the charge-inducing layer 108 may include indium aluminum nitride (In_{y}Al_{1-y}N) where y has a value less than or equal to 0.2 representing relative quantities of the respective elements. For example, y may be a value from 0 to 1 that represents relative quantities of indium and aluminum. In embodiments, y is less than or equal to 0.2. In one embodiment, y has a value of 0.18 for In_{y}Al_{1-y}N. Other values for y can be used in other embodiments. According to various embodiments, the charge-inducing layer 108 may have a higher aluminum content than the barrier layer 108 of the device 100.

According to various embodiments, the charge-inducing layer 108 has a thickness (e.g., in a direction that is substantially perpendicular to a surface of the substrate 102 upon which the buffer layer 104 is formed) that is less than a thickness that allows a parasitic channel to form between the charge-inducing layer 108 and the barrier layer 106. In some embodiments, the charge-inducing layer 108 has a thickness that is less than or equal to 60 angstroms. For example, in an embodiment where the charge-inducing layer 108 is composed of In_{0.18}Al_{0.82}N, the barrier layer 106 is composed of Al_{0.2}Ga_{0.8}N, and the cap layer 110 is composed of Al_{0.2}Ga_{0.8}N, the charge-inducing layer 108 may have a thickness that is less than or equal to 3 nanometers to inhibit formation of a parasitic channel. In an embodiment where the charge-inducing layer 108 is composed of AlN, the barrier layer 106 is composed of Al_{0.2}Ga_{0.8}N, and the cap layer 110 is composed of Al_{0.2}Ga_{0.8}N, the charge-inducing layer 108 may have a thickness that is less than or equal to 1 nanometer to inhibit formation of a parasitic channel. The charge-inducing layer 108 may include other suitable materials and/or thicknesses in other embodiments. The charge-inducing layer 108 may be composed of a plurality of deposited films or layers in some embodiments.

The stack 101 may further include a cap layer 110 formed on the charge-inducing layer 108. The cap layer 110 may be epitaxially coupled with the charge-inducing layer 108 in some embodiments. The cap layer 110 may have a bandgap energy that is less than a bandgap energy of the charge-inducing layer 108. In some embodiments, the cap layer 110 includes materials that are configured to have a low or minimal effect on channel charge density regardless of a thickness of the cap layer 110. In other embodiments, the cap layer 110 may include materials that are configured to deplete or increase channel charge for an increasing thickness of the cap layer 110. In embodiments where the cap layer 110 is configured to deplete channel charge with increasing thickness of the cap layer 110, a thickness (e.g., in a direction that is substantially perpendicular to a surface of the substrate 102 upon which the buffer layer 104 is formed) of the charge-inducing layer 108 may be increased to compensate for the charge depletion. In embodiments where the cap layer 110 is configured to increase channel charge for an increasing thickness of the cap layer 110, the thickness of the charge-inducing layer 108 may be decreased to compensate for the charge induction.

The cap layer 110 may be composed of any of a variety of suitable material systems. The cap layer 110 may include, for example, aluminum (Al), indium (In), gallium (Ga), and/or nitrogen (N). In some embodiments, the cap layer 110 may include aluminum, gallium, and nitrogen. In one embodiment, the cap layer 110 may include aluminum gallium nitride (AlₓGa₁₋ₓN), where x is a value from 0 to 1 that represents relative quantities of aluminum and gallium. In embodiments, the value for x is less than or equal to 0.2. Other values for x can be used in other embodiments. According to various embodiments, the cap layer 110 may have a lower aluminum content than the charge-inducing layer 108 of the device 100. According to various embodiments, the barrier layer 106 and the cap layer 110 may have a similar or same material composition.

According to various embodiments, the cap layer 110 may have a thickness (e.g., in a direction that is substantially perpendicular to a surface of the substrate 102 upon which the buffer layer 104 is formed) that is less than 10,000 angstroms. In some embodiments, the cap layer 110 may be composed of materials such that variation in thickness of the cap layer 110 between a range from 1 angstrom to 10,000 angstroms has little or minimal effect on channel charge density of the barrier layer 106. The cap layer 110 may include other suitable materials and/or thicknesses in other embodiments. The cap layer 110 may be composed of a plurality of deposited films or layers in some embodiments. In some embodiments, the device 100 may not include a cap layer 110 at all.

The device 100 may further include gate 118 formed in the cap layer 110 and/or in the charge-inducing layer 108, as can be seen. The gate 118 may be disposed in the charge-inducing layer 108 and coupled with the barrier layer 106 to control the channel (e.g., an on/off state of the device 100), as can be seen. The gate 118 may serve as a connection terminal for the device 100 and may be in direct physical contact with the barrier layer 106, the charge-inducing layer 108, and the cap layer 110, as can be seen. In some embodiments, the gate 118 may be formed on a dielectric layer 116 such as, for example, silicon nitride or another dielectric material that is formed on the cap layer 110, as can be seen.

The gate 118 may have a trunk or bottom portion that is coupled with the barrier layer 106 and a top portion that extends away from the trunk portion in opposing directions that are substantially parallel to a surface of the substrate 102 upon which the stack 101 is fabricated, as can be seen. Such configuration of the trunk portion and top portion of the gate 118 may be referred to as a T-shaped field-plate gate. That is, in some embodiments, the gate 118 may have an integrated field-plate (e.g., the top portion of the gate 118), which may increase a breakdown voltage and/or reduce an electric field between the gate 118 and the source 112 and/or drain 114. The field-plate may facilitate higher voltage operation of the device 100 or allow smaller device dimension in the gate-to-drain spacing for a given operating voltage.

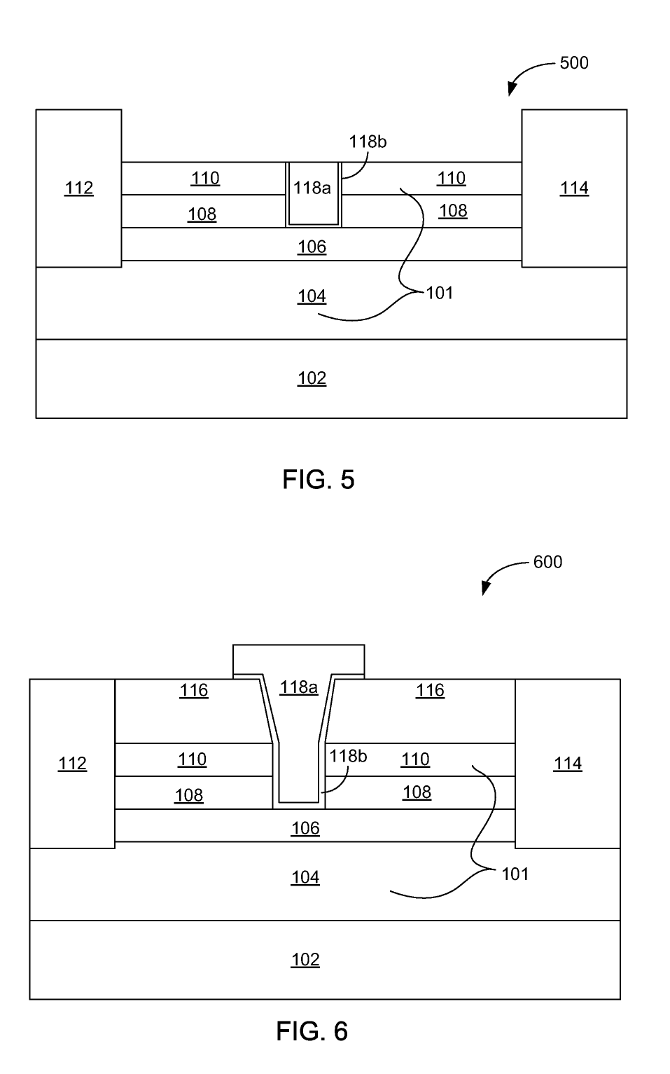

The gate 118 may include a gate electrode (e.g., gate electrode 118a of FIGS. 5-7) that provides an electrical pathway for a threshold voltage of the device 100 and a gate dielectric or gate insulator, hereinafter referred to as “gate insulator film” (e.g., gate insulator film 118b of FIGS. 5-7), that may be disposed between the gate electrode and the barrier layer 106. The gate electrode of the gate 118 is generally composed of an electrically conductive material such as a metal. In some embodiments, the gate electrode may be composed of nickel (Ni), platinum (Pt), iridium (Ir), molybdenum (Mo), gold (Au), tungsten (W), palladium (Pd) and/or aluminum (Al). In an embodiment, a material including Ni, Pt, Ir, or Mo is disposed in the trunk portion of the gate 118 to provide a gate contact with the barrier layer 106 and a material including Au is disposed in the top portion of the gate 118 to ensure conductivity and low resistance of the gate 118. According to various embodiments, the gate 118 is part of a high electron mobility transistor (HEMT) device.

In various embodiments, the gate 118 may be configured to provide a Schottky junction or MIS junction of the device 100. For example, a Schottky junction may be formed when the gate insulator film is not used at all and the MIS junction may be formed when the gate insulator film is used. The gate dielectric may be a thinner film than the gate insulator in some embodiments. The gate insulator film may include, for example, silicon nitride (SiN), silicon oxide (SiO₂), aluminum oxide (Al₂O₃), calcium fluoride (CaF₂), zirconium oxide (ZrO₂) and/or hafnium oxide (HfO₂). The gate insulator film may include other materials in other embodiments. In some embodiments, the gate insulator film may be composed of a single film or multiple films (e.g., a stack of dielectric films).

The device 100 may include a source 112 and drain 114 formed on the cap layer 110. The source 112 and the drain 114 may be coupled with the charge-inducing layer 108, as can be seen. The source 112 and the drain 114 may extend through the cap layer 110, the charge-inducing layer 108, and the barrier layer 106 into the buffer layer 104, as can be seen. According to various embodiments, the source 112 and the drain 114 are ohmic contacts. The source 112 and the drain 114 may be re-grown contacts that may provide a relatively lower contact resistance than standard grown contacts.

The source 112 and the drain 114 may be composed of an electrically conductive material such as metal. In an embodiment, the source 112 and the drain 114 may include titanium (Ti), aluminum (Al), molybdenum (Mo), gold (Au), and/or silicon (Si). Other materials can be used in other embodiments.

In an embodiment, a distance D1 between the drain 114 and the gate 118 is greater than a distance 51 between the source 112 and the gate 118. The distance D1 may be a shortest distance between the drain 114 and the gate 118 and the distance 51 may be a shortest distance between the source 112 and the gate 118 in some embodiments. Providing a shorter distance 51 than distance D1 may increase a gate 118 to drain 114 breakdown voltage and/or reduce source 112 resistance.

A dielectric layer 122 may be formed on the gate 118 and/or the dielectric layer 116 in some embodiments, as can be seen. The dielectric layer 122 may include, for example, silicon nitride (SiN). Other materials can be used for the dielectric layer 122 in other embodiments. The dielectric layer 122 may substantially encapsulate the top portion of the gate 118. The dielectric layer 122 may serve as a passivation layer of the device 100 in some embodiments.

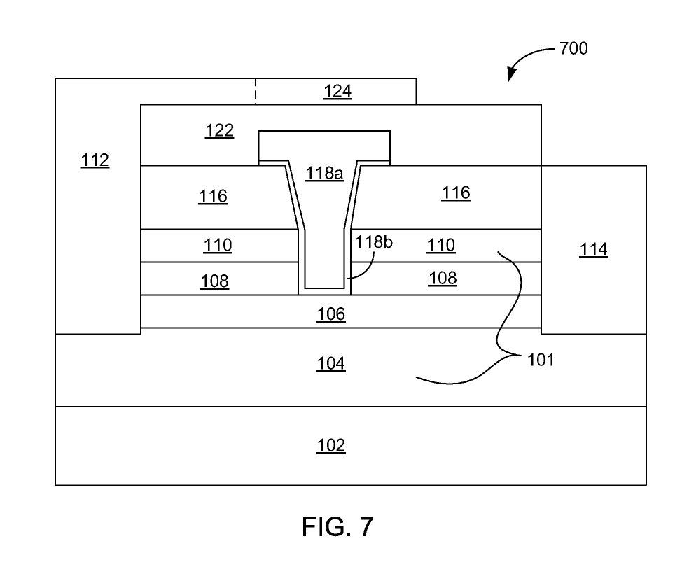

The device 100 may include a field-plate 124 formed on the dielectric layer 122 to increase a breakdown voltage and/or reduce an electric field between the gate 118 and the drain 114. The field-plate 124 may be electrically coupled with the source 112 using an electrically conductive material 126. The electrically conductive material 126 may include a metal such as, for example, gold (Au) that is deposited as an electrode or trace-like structure on the dielectric layer 122 or material of the source 112 as depicted in FIG. 7. Other suitable materials may be used for the electrically conductive material 126 in other embodiments.

The field-plate 124 may be composed of an electrically conductive material such as a metal and may include materials described in connection with the gate 118. The field-plate 124 may be capacitively coupled with the gate 118 through the dielectric layer 122. In some embodiments, a shortest distance between the field-plate 124 and the gate 118 ranges from 1 to 10,000 angstroms. The field-plate 124 may be formed over the gate 118 such that a portion of the field-plate 124 is not formed directly over the gate 118 to provide an overhanging region of the field-plate 124, as can be seen. In some embodiments, the overhanging region of the field-plate 124 extends beyond an edge of the top portion of the gate 118 by a distance H1. The distance H1 may be 0.2 to 1 micron in some embodiments. Other values for H1 may be used in other embodiments.

According to various embodiments, the device 100 may be a HEMT. In some embodiments, the device 100 may be a Schottky device. In other embodiments, the device 100 may be a MIS field-effect transistor (MISFET). For example, the gate 118 may be configured to control switching of an E-mode switch device in some embodiments. The device 100 may be used for Radio Frequency (RF), logic, envelope tracking, and/or power conversion applications. For example, the device 100 may provide an effective switch device for power-switch applications including power conditioning applications such as, for example, Alternating Current (AC)-Direct Current (DC) converters, DC-DC converters, DC-AC converters, and the like.

FIG. 2 is a graph 200 of channel charge density and barrier thickness for a variety of example barrier layer materials on GaN, according to various embodiments. In the graph 200, the channel charge density (nₛ) is depicted on a vertical axis to indicate a number of charge carriers per square centimeter (cm⁻²). The channel charge density may correspond with a 2DEG density of the device (e.g., device 100 of FIG. 1) in some embodiments. The barrier thickness is depicted on a horizontal axis in nanometers (nm).

In the graph 200, the channel charge density and barrier thickness is shown for various AlₓIn_{y}Ga_{z}N (barrier layer)/GaN HEMT structures, where x, y, and z represent values from 0 to 1 to indicate relative quantities of the respective elements. The graph 200 shows barrier layer material systems including aluminum nitride (e.g., AlN), aluminum gallium nitride (e.g., Al_{0.5}Ga_{0.5}N, Al_{0.4}Ga_{0.6}N, Al_{0.3}Ga_{0.7}N, Al_{0.2}Ga_{0.5}N, Al_{0.1}Ga_{0.9}N), and indium aluminum nitride (e.g., In_{0.18}Al_{0.82}N). As can be seen, the curves for each material system intercept the horizontal axis (where nₛ=0) at different values of barrier thickness. For each material system, the barrier thickness value where nₛ=0 corresponds with the critical thickness Tₒ for 2DEG formation.

Higher charge density may be desirable to achieve low on-resistance in a device. As can be seen, higher charge density generally corresponds with higher aluminum content in the material systems. Further, as can be seen, a higher aluminum content of the material system may result in a lower critical thickness Tₒ for 2DEG formation. Providing a barrier thickness that is less than the critical thickness (e.g., for E-mode operation) may be difficult to control or manufacture with reliable uniformity where aluminum content of the material system is higher, particularly in a case where no etch stop layer is present. Other techniques such as induction of strain on the device may be used to increase the critical thickness Tₒ for 2DEG formation.

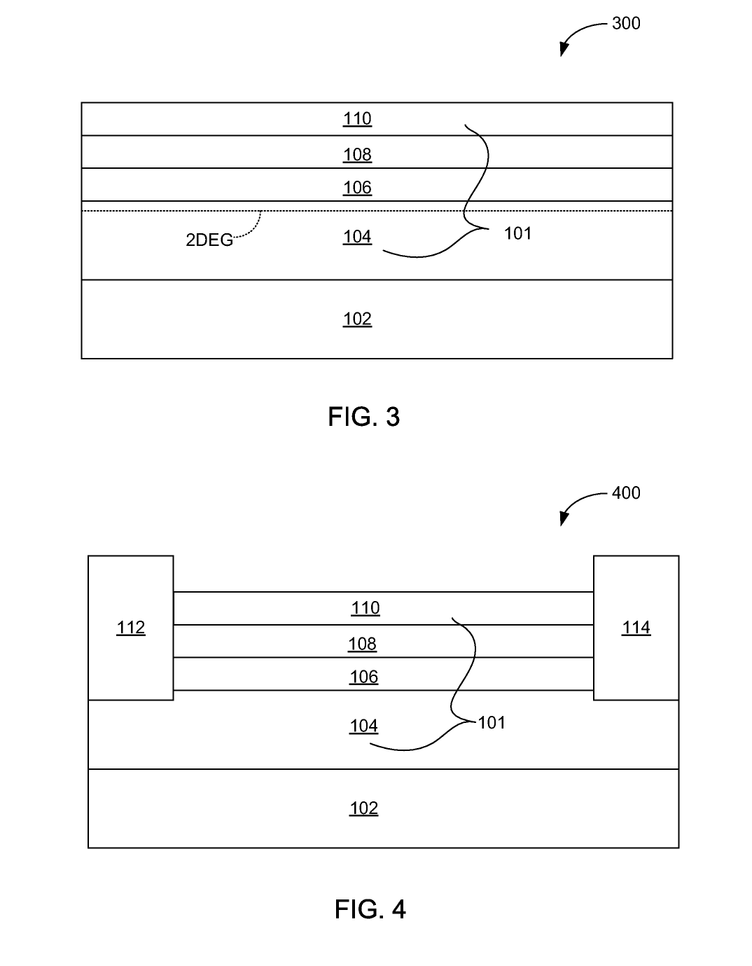

FIGS. 3-7 depict a device (e.g., device 100 of FIG. 1) subsequent to various fabrication operations. Techniques and configurations described in connection with FIGS. 3-7 may comport with embodiments described in connection with FIG. 1 and vice versa.

FIG. 3 schematically illustrates a cross-section view of a device 300 subsequent to formation of a stack of layers (e.g., stack 101) on a substrate 102, according to various embodiments. According to various embodiments, the device 300 may be fabricated by depositing a buffer layer 104 on the substrate 102, depositing a barrier layer 106 on the buffer layer 104, and depositing a charge-inducing layer 108 on the barrier layer 106. In some embodiments, a cap layer 110 may be deposited on the charge-inducing layer 108. In some embodiments, the deposition process is an epitaxial deposition process such as, for example, molecular beam epitaxy (MBE), atomic layer epitaxy (ALE), chemical beam epitaxy (CBE) and/or metal-organic chemical vapor deposition (MOCVD). Other deposition processes may be used in other embodiments. According to various embodiments, a thickness and material composition of the barrier layer 106 and charge-inducing layer 108 allows formation of a 2DEG at an interface of the buffer layer 104 and barrier layer 106, as depicted.

FIG. 4 schematically illustrates a cross-section view of a device 400 subsequent to formation of a source 112 and drain 114, according to various embodiments. The source 112 and drain 114 may be formed on the cap layer 110 in various embodiments. In an embodiment, materials such as one or more metals are deposited on the cap layer 110 in an area where the source 112 and drain 114 are to be formed using, e.g., an evaporation process. The materials used to form the source 112 and the drain 114 may include metals deposited in the following order: titanium (Ti) followed by aluminum (Al), which is followed by molybdenum (Mo), which is followed by titanium (Ti), which is followed by gold (Au). The deposited materials may be heated (e.g., to about 850° C. for about 30 seconds using a rapid thermal anneal process) to cause the materials to penetrate and fuse with underlying material of the cap layer 110, the charge-inducing layer 108, the barrier layer 106 and/or the buffer layer 104. In embodiments, each of the source 112 and the drain 114 extends through the cap layer 110 and into the buffer layer 104. A thickness of the source 112 and the drain 114 may range from 1000 to 2000 angstroms. Other thicknesses for the source 112 and the drain 114 can be used in other embodiments.

The source 112 and the drain 114 may be formed by a re-growth process to provide ohmic contacts having a reduced contact resistance or reduced on-resistance. In the re-growth process, material of the cap layer 110, the charge-inducing layer 108, the barrier layer 106 and/or the buffer layer 104 is selectively removed (e.g., etched) in areas where the source 112 and the drain 114 are to be formed. A highly doped material (e.g., n++ material) may be deposited in the areas where the layers have been selectively removed. The highly doped material of the source 112 and drain 114 may be a similar material as the material used for the buffer layer 104 or barrier layer 106. For example, in a system where the buffer layer 104 includes GaN, a GaN-based material that is highly doped with silicon (Si) or oxygen (O) may be epitaxially deposited in the selectively removed areas to a thickness of 400 to 700 Angstroms. The highly doped material can be epitaxially deposited by molecular beam epitaxy (MBE), atomic layer epitaxy (ALE), chemical beam epitaxy (CBE), or metal-organic chemical vapor deposition (MOCVD), or suitable combinations thereof. Other materials, thicknesses, or deposition techniques for the highly doped material can be used in other embodiments. One or more metals including, e.g., titanium (Ti) and/or gold (Au) can be formed/deposited on the highly doped material at a thickness ranging from 1000 Angstroms to 1500 Angstroms using, e.g., a lift-off process. Other materials, thicknesses, and/or techniques for the one or more metals can be used in other embodiments.

In some embodiments, the source 112 and the drain 114 may be formed by an implantation process that uses implantation techniques to introduce an impurity (e.g., silicon or oxygen) to provide a highly doped material in the source 112 and the drain 114. After implantation, the source 112 and the drain 114 are annealed at a high temperature (e.g., 1100-1200° C.). The re-growth process may preferably avoid the high temperature associated with the post-implantation anneal. In embodiments where a cap layer 110 is not used, the source 112 and the drain 114 may be formed on the charge-inducing layer 108 using similar techniques as described herein.

FIG. 5 schematically illustrates a cross-section view of a device 500 subsequent to formation of a gate (e.g., gate electrode 118a and gate insulator film 118b), according to various embodiments. The gate may include a gate electrode 118a and, in some embodiments, a gate insulator film 118b.

The gate may be formed in the charge-inducing layer 108 and/or the cap layer 110, as can be seen. A photomask material may be deposited and patterned (e.g., using lithography and/or etch processes) to allow selective removal of material of the cap layer 110 and/or the charge-inducing layer 108 to form an opening such as a trench where the gate materials will be deposited to form the gate. The photomask material may include, for example, photoresist materials or hardmask materials. In some embodiments, a dielectric layer (e.g., dielectric layer 116 of FIG. 6) may be deposited and patterned to provide an opening for gate formation. The dielectric layer may serve as a hardmask in some embodiments.

Embodiments of the present disclosure may provide techniques to improve uniformity of thickness of the barrier layer 106 between the gate (e.g., gate electrode 118a and/or gate insulator film 118b) and the buffer layer 104, which may improve V_{TH} control of the device 500. For example, uniformity of a barrier layer 106 thickness and, thus V_{TH}, may be determined by an etch depth of a gate recess etch process that forms the opening, a remaining thickness of the barrier layer 106 and/or charge-inducing layer 108 subsequent to the etch process, a thickness and uniformity of thickness of the gate insulator film 118b, and any variation in the process.

In one embodiment, an etch process may be used to remove material of the cap layer 110 and at least a portion of the charge-inducing layer 108. The etch process may be a timed etch process or a selective etch process. The selective etch process may include, for example, selective dry and/or plasma etching. An etch rate of material containing less aluminum may be higher than an etch rate of material containing more aluminum for etch chemistries including boron chloride (BCl₃) and/or chlorine (Cl₂), or analogous etch chemistry. Thus, in embodiments where the cap layer 110 includes a lower aluminum content than the charge-inducing layer 108, the material of the cap layer 110 may be selectively removed relative to the material of the charge-inducing layer 108.

Material of the charge-inducing layer 108 that may remain in the gate recess region subsequent to the timed etch process or the selective etch process may be removed by another selective etch process. For example, a wet etch process may be used. An etch rate of material containing more aluminum may be higher than an etch rate of material containing less aluminum for etch chemistries including potassium hydroxide (KOH) and/or tetramethyl ammonium hydroxide (TMAH), or analogous etch chemistry. Thus, in embodiments where the charge-inducing layer 108 includes a higher aluminum content than the barrier layer 106, the material of the charge-inducing layer 108 may be selectively removed relative to the material of the barrier layer 106. In some embodiments, the selective etch to remove the material of the charge-inducing layer 108 may expose the barrier layer 106. In this regard, the barrier layer 106 may serve as an etch stop layer and control the thickness for V_{TH}. Because the etch process can be stopped soon after the barrier layer 106 is exposed, the thickness (e.g., thickness T of FIG. 1) of the barrier layer 106 may be primarily controlled by the deposition thickness of the barrier layer 106.

In other embodiments, material of the charge-inducing layer 108 that may remain in the gate recess region subsequent to the timed etch process or the selective etch process (e.g., BCl₃/Cl₂) may be selectively oxidized to form the gate insulator film 118b. For example, an oxidation process may include a thermal process that is performed under ambient oxygen (O₂) or by plasma treatments. Layers with aluminum content can be oxidized (e.g., by substituting nitrogen with oxygen) to form aluminum oxide (e.g., Al₂O₃). In some embodiments, additional electrically insulative materials may be deposited to form the gate insulator film 118b. In still other embodiments, electrically insulative materials may be deposited on the barrier layer 106, the charge-inducing layer 108, and the cap layer 110 using other techniques to form the gate insulator film 118b.

The gate electrode 118a may be formed by depositing an electrically conductive material into the recessed opening of the stack 101. In embodiments where a gate insulator film 118b is used, the gate electrode 118a may be deposited on the gate insulator film 118b. The electrically conductive material may be deposited by any suitable deposition process including, for example, evaporation, atomic layer deposition (ALD) and/or chemical vapor deposition (CVD).

FIG. 6 schematically illustrates a cross-section view of a device 600 subsequent to formation of a gate (e.g., gate electrode 118a and gate insulator film 118b) having an integrated field-plate, according to various embodiments. The field-plate may be integrated in the top portion of the T-shaped field gate and may be composed of an electrically conductive material (e.g., a same or similar material as the gate electrode 118a).

In some embodiments, the device 600 may further include a dielectric layer 116 such as SiN deposited on the stack 101 to provide passivation for the channel/gate region of the device 600. The dielectric layer 116 may be patterned or recessed as part of a gate formation process using any suitable technique. In some embodiments, a profile of the gate may be more tapered in a region of the dielectric layer 116 relative to a region of the stack 101, as can be seen. Such relative tapering may be due to etch process variation of the materials and/or etch techniques. The trunk portion or top portion of the T-shaped field-plate gate may be formed by metal deposition/etch processes or a lift-off process.

FIG. 7 schematically illustrates a cross-section view of a device 700 subsequent to formation of an additional source-connected field-plate 124, according to various embodiments. A dielectric layer 122 may be formed on the dielectric layer 116 and the gate electrode 118a, as can be seen. Electrically conductive material may be deposited on the source 112 to electrically couple the source with the field-plate 124.

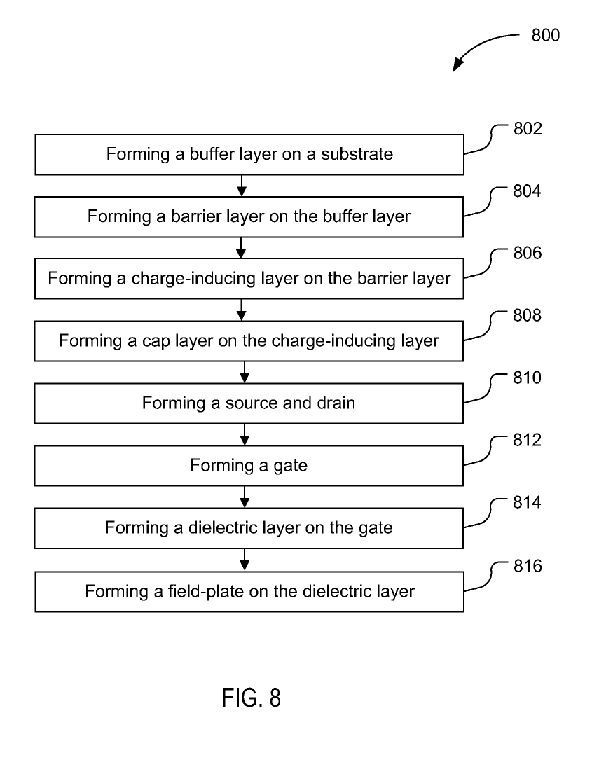

FIG. 8 is a flow diagram of a method 800 for fabricating a device (e.g., the device 100, 300, 400, 500, 600, or 700 of respective FIGS. 1. 3-7), according to various embodiments. The method 800 may comport with techniques and configurations described in connection with FIGS. 1-7.

At 802, the method 800 includes forming a buffer layer (e.g., buffer layer 104 of FIG. 1) on a substrate (e.g., substrate 102 of FIG. 1). The buffer layer may be formed using an epitaxial deposition process to deposit a buffer layer material on the substrate.

At 804, the method 800 may further include forming a barrier layer (e.g., barrier layer 106 of FIG. 1) on the buffer layer. The barrier layer may be formed using an epitaxial deposition process to deposit a barrier layer material on the buffer layer.

At 806, the method 800 may further include forming a charge-inducing layer (e.g., charge-inducing layer 108 of FIG. 1) on the barrier layer. The charge-inducing layer may be formed using an epitaxial deposition process to deposit a charge-inducing layer material on the barrier layer.

At 808, the method 800 may further include forming a cap layer (e.g., cap layer 110 of FIG. 1) on the charge-inducing layer. The cap layer may be formed using an epitaxial deposition process to deposit a cap layer material on the charge-inducing layer.

At 810, the method 800 may further include forming a source and drain (e.g., source 112 and drain 114 of FIG. 1). The source and drain may be coupled with the charge-inducing layer and extend through the charge-inducing layer and the barrier layer into the buffer layer, in some embodiments.

At 812, the method 800 may further include forming a gate (e.g., gate 118 of FIG. 1). The gate may be formed by removing a portion of the cap layer to expose a portion of the charge-inducing layer and removing a portion of the charge-inducing layer to form an opening or gate recess for deposition of gate materials. An electrically insulative material may be deposited in the opening to form a gate insulator film (e.g., gate insulator film 118b of FIG. 7). In some embodiments, the material of the gate insulator film may be deposited over the access region of the channel and may be left in such region in a final product of the device for sale or shipping to a customer. In some embodiments, removing the portion of the cap layer and/or the portion of the charge-inducing layer may be performed by timed, dry/plasma, and/or wet etch processes described herein. In some embodiments, removing the portion of the charge-inducing layer may expose the barrier layer. The barrier layer may serve as an etch stop layer for selective etching of the charge-inducing layer material. In other embodiments, removing the portion of the charge-inducing layer may not expose the barrier layer and an oxidation process may be used to replace nitrogen with oxygen and, thus, form a gate insulator film 118b on exposed layers in the recessed opening that has been formed in the stack of layers.

An electrically conductive material may be deposited in the opening to form a gate electrode (e.g., gate electrode 118a of FIG. 7). In embodiments where the gate insulator film is used, the electrically conductive material may be deposited on the gate insulator film.

At 814, the method 800 may further include forming a dielectric layer (e.g., dielectric layer 116 and/or 122 of FIG. 1) on the gate. The dielectric layer may be deposited by any suitable deposition process.

At 816, the method may further include forming a field-plate on the dielectric layer. The field-plate may be formed by depositing an electrically conductive material on the dielectric layer using any suitable deposition technique. Patterning processes such as lithography and/or etch processes can be used to selectively remove portions of the deposited electrically conductive material to form the field-plate. Other suitable techniques may be used in other embodiments.

Various operations are described as multiple discrete operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order than the described embodiment. Various additional operations may be performed and/or described operations may be omitted in additional embodiments.

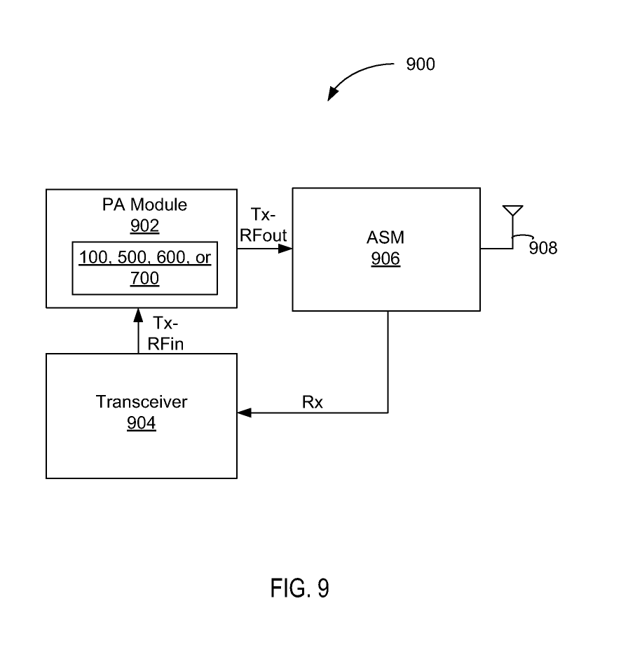

Embodiments of a device (e.g., the device 100, 500, 600, 700 of respective FIGS. 1, 5-7) described herein, and apparatuses including such device, may be incorporated into various other apparatuses and systems. FIG. 9 schematically illustrates an example system including a device, according to various embodiments As illustrated, the system 900 includes a power amplifier (PA) module 902, which may be a Radio Frequency (RF) PA module in some embodiments. The system 900 may include a transceiver 904 coupled with the power amplifier module 902 as illustrated. The power amplifier module 902 may include a device (e.g., the device 100, 500, 600, 700 of respective FIGS. 1, 5-7) described herein.

The power amplifier module 902 may receive an RF input signal, RFin, from the transceiver 904. The power amplifier module 902 may amplify the RF input signal, RFin, to provide the RF output signal, RFout. The RF input signal, RFin, and the RF output signal, RFout, may both be part of a transmit chain, respectively noted by Tx—RFin and Tx—RFout in FIG. 9.

The amplified RF output signal, RFout, may be provided to an antenna switch module (ASM) 906, which effectuates an over-the-air (OTA) transmission of the RF output signal, RFout, via an antenna structure 908. The ASM 906 may also receive RF signals via the antenna structure 908 and couple the received RF signals, Rx, to the transceiver 904 along a receive chain.

In various embodiments, the antenna structure 908 may include one or more directional and/or omnidirectional antennas, including, e.g., a dipole antenna, a monopole antenna, a patch antenna, a loop antenna, a microstrip antenna or any other type of antenna suitable for OTA transmission/reception of RF signals.

The system 900 may be any system including power amplification. The device (e.g., the device 100, 500, 600, 700 of respective FIGS. 1, 5-7) may provide an effective switch device for power-switch applications including power conditioning applications such as, for example, Alternating Current (AC)-Direct Current (DC) converters, DC-DC converters, DC-AC converters, and the like. In various embodiments, the system 900 may be particularly useful for power amplification at high radio frequency power and frequency. For example, the system 900 may be suitable for any one or more of terrestrial and satellite communications, radar systems, and possibly in various industrial and medical applications. More specifically, in various embodiments, the system 900 may be a selected one of a radar device, a satellite communication device, a mobile handset, a cellular telephone base station, a broadcast radio, or a television amplifier system.

Although certain embodiments have been illustrated and described herein for purposes of description, a wide variety of alternate and/or equivalent embodiments or implementations calculated to achieve the same purposes may be substituted for the embodiments shown and described without departing from the scope of the present disclosure. This application is intended to cover any adaptations or variations of the embodiments discussed herein. Therefore, it is manifestly intended that embodiments described herein be limited only by the claims and the equivalents thereof.

What is claimed is:

1. An apparatus comprising:
a buffer layer disposed on a substrate, the buffer layer being configured to serve as a channel of a transistor and including gallium (Ga) and nitrogen (N);
a barrier layer disposed on the buffer layer, the barrier layer being configured to supply mobile charge carriers to the channel and including aluminum (Al), gallium (Ga), and nitrogen (N);
a charge-inducing layer disposed on the barrier layer, the charge-inducing layer being configured to induce charge in the channel and including aluminum (Al) and nitrogen (N); and
a gate terminal disposed in the charge-inducing layer and coupled with the barrier layer to control the channel.

2. The apparatus of claim 1, wherein:
the charge-inducing layer has a first bandgap energy;
the barrier layer has a second bandgap energy; and
the first bandgap energy is greater than the second bandgap energy.

3. The apparatus of claim 1, wherein:
the charge-inducing layer has a first polarization;
the barrier layer has a second polarization; and
the first polarization is greater than the second polarization.

4. The apparatus of claim 1, wherein:
the barrier layer has a thickness that inhibits formation of a two-dimensional electron gas (2DEG) at a gate region disposed between the gate terminal and the buffer layer; and
the gate terminal is configured to control switching of an Enhancement mode (e-mode) high electron mobility transistor (HEMT) switch device of a power amplifier.

5. The apparatus of claim 1, further comprising:
a cap layer disposed on the charge-inducing layer, the cap layer including aluminum (Al), gallium (Ga), and nitrogen (N).

6. The apparatus of claim 5, wherein:
the buffer layer includes gallium nitride (GaN);
the barrier layer and the cap layer include aluminum gallium nitride (AlₓGa₁₋ₓN) where x has a value less than or equal to 0.2 representing relative quantities of the respective elements; and
the charge-inducing layer includes indium aluminum nitride (In_{y}Al_{1-y}N) where y has a value less than or equal to 0.2 representing relative quantities of the respective elements.

7. The apparatus of claim 6, wherein:
the barrier layer has a thickness that is greater than or equal to 30 angstroms;
the charge-inducing layer has a thickness that is less than or equal to 30 angstroms; and
the cap layer has a thickness that is less than or equal to 10,000 angstroms.

8. The apparatus of claim 1, wherein the gate terminal includes a gate electrode that is coupled with material of the barrier layer to form a Schottky junction.

9. The apparatus of claim 1, wherein:
the gate terminal includes a gate electrode and a gate insulator coupled with material of the barrier layer to form a metal-insulator-semiconductor (MIS) junction.

10. The apparatus of claim 1, further comprising:
a source coupled with the charge-inducing layer; and
a drain coupled with the charge-inducing layer, wherein the source and the drain extend through the charge-inducing layer and the barrier layer into the buffer layer.

11. The apparatus of claim 10, further comprising:
a dielectric material disposed on the charge-inducing layer, the dielectric material encapsulating a portion of the gate terminal.

12. The apparatus of claim 11, wherein:
the gate terminal is a T-shaped field-plate gate; and
the gate terminal includes nickel (Ni), platinum (Pt), iridium (Ir), molybdenum (Mo), or gold (Au).

13. The apparatus of claim 12, further comprising:
a field-plate disposed on the dielectric material, the field-plate being electrically coupled with the source and capacitively coupled with the gate terminal through the dielectric material.

14. The apparatus of claim 1, further comprising:
the substrate, the substrate including silicon (Si), silicon carbide (SiC), sapphire (Al₂O₃), gallium nitride (GaN), diamond (C), silicon oxide (SiO₂), or aluminum nitride (AlN).

15. The apparatus of claim 14, wherein:
the buffer layer is epitaxially coupled with the substrate;
the barrier layer is epitaxially coupled with the buffer layer; and
the charge-inducing layer is epitaxially coupled with the barrier layer.

16. The apparatus of claim 15, wherein the buffer layer, the barrier layer, or the charge-inducing layer is composed of multiple layers.

17. A method comprising:
forming a buffer layer on a substrate, the buffer layer being configured to serve as a channel of a transistor and including gallium (Ga) and nitrogen (N);
forming a barrier layer on the buffer layer, the barrier layer being configured to supply mobile charge carriers to the channel and including aluminum (Al), gallium (Ga), and nitrogen (N);
forming a charge-inducing layer on the barrier layer, the charge-inducing layer being configured to induce charge in the channel and including aluminum (Al) and nitrogen (N); and
forming a gate terminal in the charge-inducing layer, the gate terminal being coupled with the barrier layer to control the channel.

18. The method of claim 17, wherein:
forming the buffer layer includes epitaxially depositing a buffer layer material on the substrate;
forming the barrier layer includes epitaxially depositing a barrier layer material on the buffer layer; and
forming the charge-inducing layer includes epitaxially depositing a charge-inducing layer material on the barrier layer, wherein the charge-inducing layer has a first polarization, the barrier layer has a second polarization and the first polarization is greater than the second polarization.

19. The method of claim 18, wherein forming the charge-inducing layer includes epitaxially depositing a charge-inducing layer material on the barrier layer, wherein the charge-inducing layer has a first bandgap energy, the barrier layer has a second bandgap energy and the first bandgap energy is greater than the second bandgap energy.

20. The method of claim 18, further comprising
forming a cap layer on the charge-inducing layer by epitaxially depositing a cap layer material on the charge-inducing layer, the cap layer including aluminum (Al), gallium (Ga), and nitrogen (N).

21. The method of claim 20, wherein:
the buffer layer material includes gallium nitride (GaN);
the barrier layer material and the cap layer material include aluminum gallium nitride (AlₓGa₁₋ₓN) where x has a value less than or equal to 0.2 representing relative quantities of the respective elements; and
the charge-inducing layer material includes indium aluminum nitride (In_{y}Al_{1-y}N) where y has a value less than or equal to 0.2 representing relative quantities of the respective elements.

22. The method of claim 21, wherein:
forming the barrier layer provides a barrier layer thickness that is less than or equal to 60 angstroms;
forming the charge-inducing layer provides a charge-inducing layer thickness that is less than or equal to 30 angstroms; and
forming the cap layer provides a cap layer thickness that is less than or equal to 10,000 angstroms.

23. The method of claim 22, wherein:
the barrier layer thickness inhibits formation of a two-dimensional electron gas (2DEG) at a gate region disposed between the gate terminal and the buffer layer; and
the gate terminal is configured to control switching of an Enhancement mode (e-mode) high electron mobility transistor (HEMT) device.

24. The method of claim 20, wherein forming the gate terminal comprises:
removing a portion of the cap layer to expose the charge-inducing layer; and
removing a portion of the charge-inducing layer.

25. The method of claim 24, wherein:
removing the material of the cap layer comprises selectively etching the cap layer material using boron chloride (BCl₃) or chlorine (Cl₂); and
removing the portion of the charge-inducing layer comprises selectively etching the charge-inducing layer material using potassium hydroxide (KOH) or tetramethyl ammonium hydroxide (TMAH).

26. The method of claim 25, wherein:
removing the portion of the charge-inducing layer exposes the barrier layer; and
the barrier layer serves as an etch stop layer for the selective etching of the charge-inducing layer material.

27. The method of claim 25, wherein forming the gate terminal further comprises:
depositing a gate electrode material in a region where the cap layer material and the charge-inducing layer have been removed, the gate electrode material being coupled with the material of the barrier layer to form a Schottky junction.

28. The method of claim 25, wherein forming the gate terminal further comprises:
selectively oxidizing the charge-inducing layer material that is exposed by removing the portion of the charge-inducing layer to form a gate insulator; and
depositing a gate electrode material on the gate insulator, the gate electrode and the gate insulator being coupled with the barrier layer material to form a metal-insulator-semiconductor (MIS) junction.

29. The method of claim 17, further comprising:
forming a source and drain coupled with the charge-inducing layer, wherein the source and the drain extend through the charge-inducing layer and the barrier layer into the buffer layer.

30. The method of claim 29, further comprising:
depositing a dielectric material on the charge-inducing layer, the dielectric material encapsulating a portion of the gate terminal.

31. The method of claim 30, wherein the gate terminal is a T-shaped field-plate gate, the method further comprising:
forming a field-plate on the dielectric material, the field-plate being electrically coupled with the source and capacitively coupled with the gate terminal through the dielectric material.
